(19) United States
(12) Patent Application Publication
(10) Pub. No.: US 2026/0361130 A1
(43) Pub. Date: Nov. 12, 2026

(54) RECOGNITION-GEOMETRY CROSS-DOMAIN ENERGY-HARVESTING PLATFORM

(71) Applicant: Jonathan Washburn, Austin, TX (US)

(72) Inventor: Jonathan Washburn, Austin, TX (US)

(21) Appl. No.: 19/675,130

(22) Filed: May 12, 2026

Related U.S. Application Data
(60) Provisional application No. 63/804,608, filed on May 12, 2025.

(51) Int. Cl. H02J 50/00; H02N 11/00; H03J 1/00

(52) U.S. Cl. CPC H02J 50/001; H02J 50/005; H02N 11/002; H03J 1/0058

(57) ABSTRACT

A cross-domain energy-harvesting platform includes a shared chi-lattice resonator substrate, at least two tile families harvesting energy from physically distinct domains on and aligned to the shared chi-lattice resonator substrate, a common chi-bus backplane electrically coupling the tile families, and a recognition-guided adaptive controller configured to coordinate extraction and aggregation across the domains. In disclosed embodiments, the chi-lattice resonator has an odd-index mode family defined by m_n=2n+1, the controller ranks active channels by J-cost, extraction is gated to permitted windows within an eight-tick cadence, and all energy transfers on the platform are quantized to integer multiples of E_coh=phi\hat{ }−5. Preferred tile families include vibration, mid-IR rectenna, thermoradiative, and near-field thermophotovoltaic tile families implemented as modular embodiments on the shared chi-lattice resonator substrate.

### CROSS-REFERENCE TO RELATED APPLICATIONS

This application claims the benefit of U.S. Provisional Patent Application No. 63/804,608, filed May 12, 2025, the entire disclosure of which is incorporated herein by reference.

### BACKGROUND OF THE INVENTION

This invention relates generally to energy-harvesting systems and, more particularly, to chi-lattice-resonator-based cross-domain energy-harvesting platforms in which at least two physically distinct transduction modalities are implemented on and aligned to a shared chi-lattice resonator substrate, are electrically coupled through a common chi-bus backplane, and are coordinated by a recognition-guided adaptive controller. In the disclosed platform architecture, the shared chi-lattice resonator substrate, the common chi-bus backplane, and the recognition-guided adaptive controller cooperate to aggregate and dispatch harvested energy as one platform rather than as separately managed devices.

Conventional energy-harvesting systems typically target only a single harvesting modality, such as vibration, thermal radiation, or another isolated ambient source. As a result, such systems tend to consume substrate area inefficiently, duplicate associated electronics and power-conditioning structures, and fail to take advantage of environments in which multiple energy streams are simultaneously present. In many practical settings, including industrial, transportation, and built-environment contexts, useful energy is available concurrently in different physical forms, yet existing single-domain harvesters generally remain confined to one source type and therefore underutilize the available environment.

Attempts to combine multiple sources have also been limited. Known hybrid harvesters may place two source types in parallel or otherwise combine outputs in an ad hoc manner, but such arrangements generally lack a shared resonator geometry and lack a principled dispatch framework for determining when, how, and from which source energy should be extracted. As a consequence, these hybrid arrangements often amount to side-by-side coexistence of different harvester types rather than true platform-level integration.

Conventional control approaches also present limitations. Maximum power point tracking techniques are commonly designed around smooth and substantially monotonic power-voltage behavior. However, modal transducers, including rectenna structures, magnetostrictive devices, and near-field cavity-based devices, may exhibit discrete operating points, phase-sensitive behavior, or other non-monotonic operating characteristics for which generic MPPT approaches are not well suited. Accordingly, existing control architectures do not adequately address coordinated extraction across plural distinct-domain harvesting channels operating under different physical conditions on a common platform.

Existing systems also fail to provide a common substrate architecture capable of supporting multiple physically distinct harvesting domains on one platform. Prior arrangements generally rely on separately fabricated devices, separate support structures, or substrate arrangements lacking common fiducials and lacking a cross-scale resonator geometry capable of supporting optical, thermal, and elastic modalities within a unified framework. This absence of a shared substrate architecture contributes to fabrication complexity, inter-device registration difficulty, and limited platform integration.

Existing platforms further lack formal correctness assurances of the type needed for coordinated multi-domain operation. Known systems generally do not provide machine-verified guarantees of positive aggregate output, valid dispatch phase existence, or true cross-domain operation under a unified platform architecture. As a result, prior systems have not adequately addressed the need for an integrated platform that can coordinate plural harvesting domains with principled dispatch and platform-level correctness.

Accordingly, a need remains for a cross-domain energy-harvesting platform capable of unifying multiple physically distinct harvester domains on one substrate, one bus, and one controller while preserving principled dispatch, electrical aggregation, and platform-level correctness.

### SUMMARY OF THE INVENTION

The present disclosure provides a cross-domain energy-harvesting platform comprising a shared chi-lattice resonator substrate, at least two tile families configured to harvest energy from physically distinct domains on and aligned to the shared chi-lattice resonator substrate, a common chi-bus backplane electrically coupling the tile families, and a recognition-guided adaptive controller configured to coordinate extraction and aggregation across the domains. The invention claims the platform as a whole. The shared chi-lattice resonator substrate is the disclosed unifying substrate framework, the common chi-bus backplane is the common bus architecture through which harvested energy is electrically aggregated, and the recognition-guided adaptive controller provides the cross-domain control strategy by which distinct-domain channels are evaluated, ranked, gated, and dispatched as one platform rather than as separately managed harvesters.

In disclosed embodiments, the chi-lattice resonator substrate provides a shared physical framework on which at least two physically distinct tile families are implemented and aligned.

The resonator framework includes an odd-index mode family in which m_n=2n+1. Because m_n=2n+1 are always odd, odd symmetry ensures that transverse strain nodes coincide with longitudinal optical antinodes, thereby enabling simultaneous mechanical and electromagnetic resonance on the same substrate. The same odd-index chi-lattice mode family supports cross-scale operation across optical, thermal, and elastic regimes by variation of base pitch while preserving the same resonator framework. Common-fiducial alignment of plural tile families on the same substrate reduces or eliminates inter-tile registration error associated with separately fabricated hybrid systems.

In disclosed embodiments, the recognition-guided adaptive controller ranks active channels by J-cost, gates extraction to permitted windows within the eight-tick cadence, and quantizes all energy transfers on the platform to integer multiples of E_coh, where E_coh=phi\hat{ }−5. In disclosed embodiments, the coherence exponent=5 is preserved where identified as forced, certified, or family-verified, and the platform-level timing and transfer logic are grounded in exact recognition-geometry relationships rather than generic synchronization or generalized power optimization. The controller evaluates channel state using a recognition ratio and ranks active channels by ascending J-cost so that channels closer to ratio unity receive dispatch priority. The phase-cancellation identity sum_{k=0}\hat{ }{7} exp(2pii*k/8)=0 forces an eight-phase ledger cycle, and the disclosed controller architecture gates extraction within that cycle so that every complete cycle leaves the ledger exactly neutral. In disclosed embodiments, phase-locked bundle dispatch occurs when plural channels share a common admissible phase, and at least one admissible dispatch phase exists.

In disclosed embodiments, preferred tile families include vibration tile families, mid-IR rectenna tile families, thermoradiative tile families, and near-field TPV tile families fabricated on and aligned to the shared chi-lattice resonator substrate and electrically coupled through the common chi-bus backplane. These preferred tile families are exemplary implementations of the disclosed platform and do not redefine the invention away from the chi-lattice-resonator-based platform architecture itself. The platform may also be embodied in two-domain minimum configurations and other supported subset combinations consistent with the disclosed shared substrate, common bus architecture, and recognition-guided adaptive controller.

In disclosed embodiments, the common chi-bus backplane is a passive and lossy, not generative, electrical aggregation structure. The chi-bus may include impedance-matching structures, including phi-ladder impedance matching, current sensing, bias adjustment, storage coupling, and load interfacing. The disclosure also supports theorem-backed platform properties including positive aggregate output, positive net output for positive-power channels and positive bus efficiency, and net output less than or equal to gross output.

The disclosure further includes machine-verified platform invariants, family certificates, worked numerical examples, and engineering reliability results. These support materials are presented in separate descriptive lanes so that engineering-measured material, machine-verified material, worked examples, and prophetic or future-facing embodiments remain distinct. Downstream applications, specific tile counts, panel sizes, and commercial sectors are examples only and do not define the invention. Broad claim paths, narrower controller-focused and substrate-focused fallback positions, fabrication method concepts, software or firmware medium claims, verification-based fallback positions, manufactured-article and installation-oriented claim positions, and downstream system or use claims are all supported by the present disclosure.

### BRIEF DESCRIPTION OF THE DRAWINGS

FIG. 1 is a platform architecture view showing the shared chi-lattice resonator substrate, plural tile families, a common chi-bus backplane, and a recognition-guided adaptive controller.

FIG. 2 is a resonator-geometry view showing the chi-lattice structure, common chi-apex fiducials, an odd-index mode family, and a shared substrate stack.

FIG. 3 is a mode-spectrum view showing cross-scale continuity of the same odd-index chi-lattice mode family across optical, thermal, and elastic regimes.

FIG. 4 is a modular tile architecture view showing representative vibration, mid-IR rectenna, thermoradiative, and near-field TPV tile structures implemented on the shared chi-lattice resonator substrate.

FIG. 5 is a backplane and power-management view showing the common chi-bus, impedance matching, current monitoring, storage coupling, and an external load interface.

FIG. 6 is a controller flow view showing channel-state intake, recognition-ratio evaluation, J-cost ranking, phase evaluation, dispatch gating, quantized transfer control, and optional telemetry output.

FIG. 7 is an eight-tick timing view showing permitted windows, phase-locked bundle dispatch, and ledger-neutral cycle completion.

FIG. 8 is a fabrication flow view showing substrate formation, fiducial patterning, sequential tile deposition, bus formation, and final assembly.

FIG. 9 is a baseline power-flow and output example view.

FIG. 10 is a reliability and validation view showing qualification conditions, degradation behavior, and verification anchors.

FIG. 11 is a two-domain minimum embodiment view showing breadth-preserving operation with fewer than four tile families.

### DETAILED DESCRIPTION OF THE INVENTION

The present disclosure describes a cross-domain energy-harvesting platform in which multiple physically distinct harvesting modalities are integrated into a unified platform architecture. The invention claims the platform as a whole. The disclosed platform is defined by the co-equal integration of a shared chi-lattice resonator substrate, a common chi-bus backplane, and a recognition-guided adaptive controller. The shared chi-lattice resonator substrate is the disclosed unifying substrate framework on which plural distinct-domain tile families are implemented and aligned. The common chi-bus backplane electrically couples those tile families into a common aggregation architecture. The recognition-guided adaptive controller ranks active channels by J-cost, gates extraction to permitted windows within the eight-tick cadence, and quantizes all energy transfers on the platform to integer multiples of E_coh, where E_coh=phi\hat{ }−5. In disclosed embodiments, the coherence exponent=5 is preserved where identified as forced, certified, or family-verified, and the platform-level timing and transfer logic are grounded in exact recognition-geometry relationships rather than generic synchronization or generalized power optimization. Individual transducer mechanisms may be implemented using one or more preferred tile families, but the invention is not defined by any single tile family, any single application environment, or any downstream deployment context. The invention is directed to the platform-level architecture by which plural harvesting domains are unified.

In conventional practice, harvesting devices are ordinarily developed as single-domain structures that convert one ambient source into electrical energy while ignoring other coexisting sources in the same environment. A vibration harvester may be mounted on a mechanical assembly, a thermal harvester may be positioned near a heat source, and an optical or radiative harvesting structure may be deployed independently elsewhere. Even where more than one harvester type is used, such devices are often separately fabricated, separately mounted, separately conditioned, and separately controlled. That approach duplicates support structure, duplicates power-conditioning hardware, complicates integration, and leaves substantial ambient energy uncaptured. The present disclosure addresses that problem through a platform architecture in which at least two physically distinct harvesting domains are implemented on and aligned to the same shared chi-lattice resonator substrate, electrically coupled through the same common chi-bus backplane, and coordinated through the same recognition-guided adaptive controller so that heterogeneous energy streams are dispatched and aggregated as one system rather than as isolated source-specific devices.

The platform-level identity of the invention should be understood at the outset. The shared chi-lattice resonator substrate is not merely a mounting layer. The common chi-bus backplane is not merely wiring. The recognition-guided adaptive controller is not merely supervisory logic. These three elements cooperate as co-equal architectural pillars. The shared chi-lattice resonator substrate provides the disclosed resonant and alignment framework by which multiple distinct-domain tile families can coexist on one physical platform. The common chi-bus backplane provides the electrical aggregation structure through which harvested energy and associated control or sensing signals are routed. The recognition-guided adaptive controller provides the cross-domain control strategy by which active channels are evaluated, ranked, phase-checked, and dispatched according to a platform-wide rule set. These platform pillars collectively distinguish the invention from ad hoc hybrid combinations in which different source converters are merely placed side by side without a common resonator logic, without a common bus architecture, and without a principled dispatch discipline.

As used herein, the term “platform” refers to an integrated energy-harvesting architecture including a shared chi-lattice resonator substrate, a common chi-bus backplane, a recognition-guided adaptive controller, and at least two harvesting tile families configured to operate together as a coordinated system. The platform may additionally include storage structures, output structures, packaging structures, sensing structures, telemetry structures, encapsulation structures, interface structures, or combinations thereof, but those auxiliary elements do not displace the three principal platform pillars identified above. A platform in the present sense therefore differs from a mere collection of separate energy harvesters because the present platform is organized around common resonator geometry, common electrical aggregation, and common recognition-guided control.

As used herein, the term “tile family” refers to a class of modular energy-harvesting structures sharing a domain-specific transduction mechanism and configured for implementation on or in association with the shared chi-lattice resonator substrate. A tile family may include one or more repeated tile units, one or more variant tile geometries, one or more material-stack variants, one or more mode selections, one or more packaging variants, or one or more coupling variants, provided that the tile family remains operable as part of the disclosed platform architecture. A tile family is therefore not limited to one exact microstructure or one exact materials recipe.

Rather, the tile family concept allows domain-specific implementations to vary while remaining integrated into the common substrate, bus, and controller framework.

As used herein, the term “physically distinct domain” refers to a harvesting domain that differs in physical operating basis from another harvesting domain. By way of example, and not limitation, physically distinct domains may include mechanical vibration harvesting, mid-infrared radiative harvesting, thermoradiative harvesting, near-field thermophotovoltaic harvesting, or other harvesting domains implemented consistently with the shared chi-lattice resonator substrate, the common chi-bus backplane, and the recognition-guided adaptive controller architecture described herein. The phrase “at least two physically distinct domains” is used intentionally and should not be softened into a vague reference to multiple sources. The invention is cross-domain in the sense that it requires at least two harvesting channels based on different physical operating principles.

As used herein, the term “shared substrate” refers to a common physical support and resonator framework on which plural tile families are formed, aligned, implemented, supported, or otherwise integrated so that the plural tile families operate as part of one platform rather than as separately fabricated hybrid devices that are later combined. A shared substrate in the present disclosure is preferably a shared chi-lattice resonator substrate. Broader claim language may in some contexts refer to a shared resonant substrate, but the disclosed unifying substrate framework of the specification is the shared chi-lattice resonator substrate.

As used herein, the term “chi-lattice resonator” refers to the disclosed resonator framework defined by counter-diagonal chi-geometry, common chi-apex fiducials, and an odd-index mode family that supports cross-scale resonant behavior across optical, thermal, and elastic regimes.

The chi-lattice resonator is therefore not just a pattern applied for appearance or registration. It is the disclosed physical and geometric framework by which plural distinct-domain tile families are unified on one substrate.

As used herein, the term “chi-bus backplane” refers to the common electrical backplane through which harvested energy, control signaling, sensing information, phase-related information, bias-adjustment information, telemetry information, or combinations thereof are routed among tile families, controller structures, storage structures, and load structures. The chi-bus backplane may be implemented in different electrical forms consistent with the present disclosure, but in preferred embodiments it provides a common bus architecture carrying both electrical aggregation and control functionality.

As used herein, the term “channel” refers to an active or potentially active harvesting path associated with a particular domain implementation, tile family, tile grouping, or dispatchable harvesting element. A channel may be characterized by one or more values including, for example, a harvesting domain, a recognition ratio, a phase state, a power-density value, a bus state, a bias state, or a dispatch availability state.

As used herein, the term “recognition ratio” refers to a controller input or derived controller value representative of channel state and used in evaluating channel priority under the recognition-guided adaptive controller. In one non-limiting implementation, the recognition ratio is computed from measurable electrical channel-state information including a bus-side voltage Vch and a bus-side current Ich according to x=(Vch*Ich)/Pref, where Pref is a stored reference power associated with the channel, channel family, calibration state, or combinations thereof. As used herein, the symbol “*” denotes multiplication in ASCII notation. The recognition ratio is used in calculating J-cost and is therefore part of the disclosed dispatch logic by which channels are ranked and selected.

As used herein, the term “J-cost” refers to the channel-scoring quantity J(x)=½(x+1/x)−1. In disclosed embodiments, the controller evaluates J-cost for active channels and ranks those active channels by ascending J-cost so that a channel closer to ratio unity is preferred for dispatch. The phrase “ranks active channels by J-cost” should be read as an exact architectural proposition of the disclosed controller logic rather than a loose analogy to generalized optimization.

As used herein, the term “eight-tick cadence” refers to the eight-phase controller timing discipline associated with ledger-neutral dispatch. A “permitted dispatch window” refers to a phase interval within that eight-tick cadence during which extraction is permitted. A “phase-locked bundle” refers to plural channels sharing a common admissible phase for coordinated dispatch. “E_coh-locked transfer” and “E_coh-quantized transfer” refer to transfer quantized to integer multiples of E_coh, where E_coh=phi\hat{ }−5. “Dimensionless transfer” and “policy transfer” refer to transferability of controller policies expressed in dimensionless recognition coordinates across recalibration conditions without changing the argmin set. These definitions are intended to preserve exact terminology for later use throughout the specification and claims and should not be weakened into generalized references to timing, synchronization, or efficiency-based control.

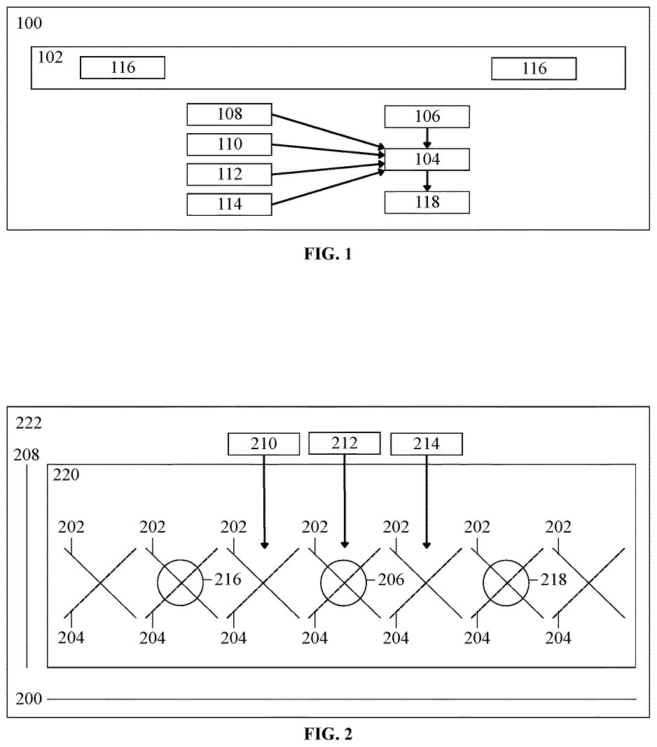

With reference now to FIG. 1, a platform 100 includes a shared chi-lattice resonator substrate 102, a common chi-bus backplane 104, and a recognition-guided adaptive controller 106. The platform 100 further includes one or more vibration tile family structures 108, one or more mid-IR rectenna tile family structures 110, one or more thermoradiative tile family structures 112, and one or more near-field TPV tile family structures 114. Common chi-apex fiducials 116 may be distributed across the shared chi-lattice resonator substrate 102 to facilitate alignment, registration, and fabrication continuity. Harvested output may be routed to an output or load interface 118. FIG. 1 therefore depicts the platform-level relationship between the shared chi-lattice resonator substrate 102, the common chi-bus backplane 104, the recognition-guided adaptive controller 106, and plural tile families 108, 110, 112, and 114. This figure is intended to make the core invention visually unmistakable as a platform architecture rather than as any single tile family alone.

The shared chi-lattice resonator substrate is the disclosed unifying substrate framework by which plural distinct-domain tile families are implemented and aligned on one platform. In preferred embodiments, the shared chi-lattice resonator substrate comprises a resonator framework formed by counter-diagonal strokes inscribed in or on a selected substrate stack. Common chi-apex fiducials are provided to support repeated alignment across deposition and formation steps associated with different tile families. This common-fiducial alignment of plural tile families on the same substrate reduces or eliminates inter-tile registration error associated with separately fabricated hybrid systems. Accordingly, the shared chi-lattice resonator substrate is part of the core structural mechanism of the platform and should not be treated as a minor fabrication preference. The common-substrate, common-fiducial approach is central to how the invention departs from prior hybrid architectures that combine separately fabricated devices after the fact.

With reference to FIG. 2, a resonator framework 200 includes a first counter-diagonal stroke set 202 and a second counter-diagonal stroke set 204 arranged in chi-lattice form. A chi-apex fiducial 206 is provided as a common alignment reference. The resonator framework 200 is associated with a base pitch P0 shown at 208 and with an odd-index mode family including, by way of example, odd mode m1 at 210, odd mode m3 at 212, and odd mode m5 at 214. A transverse strain node 216 and a longitudinal optical antinode 218 are positioned to illustrate the structural relationship by which odd symmetry ensures that transverse strain nodes coincide with longitudinal optical antinodes. The resonator framework 200 may be formed in or on a membrane layer 220 supported by a support substrate 222. In preferred embodiments, the membrane layer 220 comprises a low-stress Si3N4 layer and the support substrate 222 comprises SiO2, although other substrate-stack implementations may be employed so long as they preserve the disclosed chi-lattice resonator framework and common-fiducial alignment approach.

The mode numbers of the disclosed resonator framework satisfy m_n=2n+1. Accordingly, m_n=2n+1 are always odd. This odd-index mode family is structurally significant and not decorative. Odd symmetry ensures that transverse strain nodes coincide with longitudinal optical antinodes, thereby enabling simultaneous mechanical and electromagnetic resonance on the same substrate. The mode pitch relation may be expressed as P_n=P0*m_n, such that the same odd-index chi-lattice mode family supports cross-scale operation across optical, thermal, and elastic regimes through variation of the base pitch P0 while preserving the same resonator framework.

In disclosed embodiments, theorem-backed support includes verification that the odd-index mode family remains odd, that mode pitch remains positive across the disclosed resonator family, and that the shared chi-lattice resonator framework preserves cross-scale continuity across optical, thermal, and elastic regimes. That proposition is important because it supplies a concrete mechanism for why one substrate family can host harvesting structures associated with multiple physically distinct domains. The present disclosure therefore does not rely on an undefined notion of “multi-purpose support.” Rather, it discloses a common chi-lattice resonator framework having specific odd-index modal behavior and specific node-antinode coincidence relationships that enable cross-domain integration.

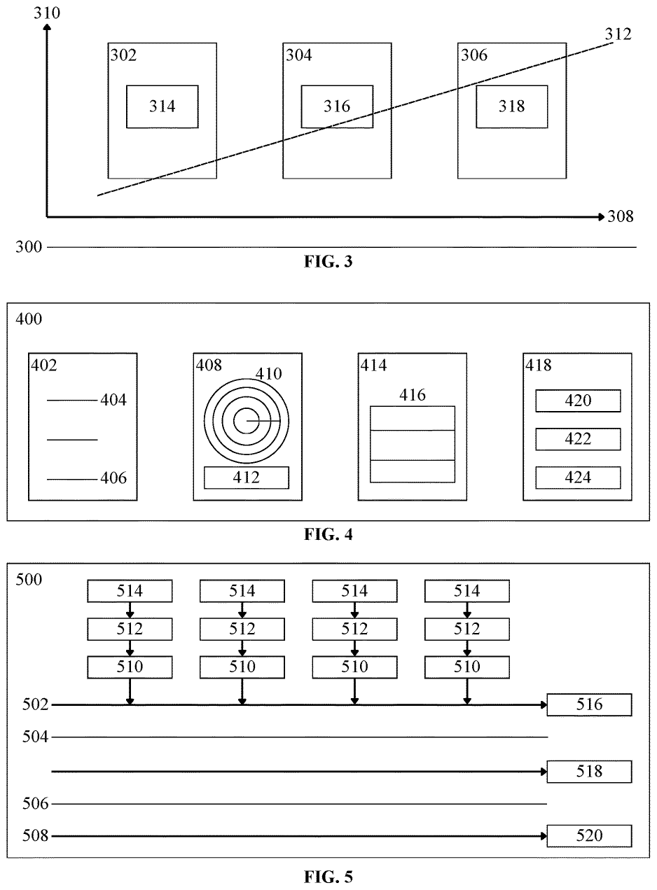

With reference to FIG. 3, a mode-spectrum chart 300 depicts operation across an optical regime 302, a thermal regime 304, and an elastic regime 306. A mode pitch P_n is shown at 308, a base pitch P0 is shown at 310, and the odd-index mode family is shown at 312. Representative operating regions may include a rectenna operating region 314, a thermoradiative operating region 316, and a vibration operating region 318. FIG. 3 illustrates that the same odd-index chi-lattice mode family supports cross-scale operation across optical, thermal, and elastic regimes through variation of base pitch P0 while preserving the same resonator framework. In preferred embodiments, optical-scale implementation may correspond to rectenna and near-field TPV operation, thermal-scale implementation may correspond to thermoradiative operation, and elastic-scale implementation may correspond to vibration harvesting. This cross-scale continuity is a major point of distinction over architectures in which multiple harvesting domains are merely placed in proximity without a common resonator logic.

In preferred fabrication implementations, the resonator framework may be formed on a SiO2 substrate with a low-stress Si3N4 membrane, and the process flow may be selected to remain compatible with CMOS back-end integration, for example with a membrane thickness of about 500 nm in one preferred implementation and overlay alignment on the order of about 50 nm in one preferred implementation. Such material and process selections are preferred implementation details rather than universal claim requirements. The central point is that plural distinct-domain tile families are aligned to common chi-apex fiducials on the same chi-lattice resonator substrate and therefore inherit a common resonator geometry, a common alignment basis, and a common fabrication framework. This common-substrate, common-fiducial approach reduces or eliminates inter-tile registration error associated with separately fabricated hybrid assemblies and strengthens both structural integration and manufacturing repeatability. These substrate-side propositions should be understood as part of the core structural mechanism of the invention and not merely as fallback fabrication detail.

The shared chi-lattice resonator substrate also serves as the basis for the platform's non-generic identity. If plural harvesting tile families were simply mounted on a board or attached to an arbitrary panel, the result would not provide the disclosed substrate-side mechanism of the present invention. In the present disclosure, the shared chi-lattice resonator substrate is the disclosed unifying substrate framework. It is the common resonator geometry through which plural tile families are implemented and aligned. It is the basis on which common-fiducial alignment of plural tile families on the same substrate is achieved. It is the framework through which the same odd-index chi-lattice mode family supports cross-scale operation across optical, thermal, and elastic regimes. The present platform architecture should therefore be understood as substrate-led, bus-integrated, and controller-coordinated, with each of those elements acting as a co-equal pillar of the invention.

The platform may be understood generically as a collection of DomainChannel structures implemented on the shared chi-lattice resonator substrate and coordinated through the common chi-bus backplane by the recognition-guided adaptive controller. Each DomainChannel corresponds to a harvesting path associated with a particular tile family, tile grouping, or domain implementation and may be characterized by a harvesting domain, a recognition ratio, a phase tag, and a power-density contribution. In some embodiments, a DomainChannel may also be associated with bias state information, current state information, bus-headroom information, dispatch-availability information, or combinations thereof. The DomainChannel concept is useful because it separates the platform-level control logic from any one transduction mechanism. The controller can therefore evaluate, rank, and dispatch channels according to a common rule set even though the underlying physical source mechanisms differ from one another.

At least two physically distinct domains are required for the platform character of the invention.

Stated differently, the disclosed platform is cross-domain by virtue of hosting at least two harvesting channels based on different physical operating principles on the same shared chi-lattice resonator substrate and under the same common bus architecture and recognition-guided control strategy. The invention does not require that every embodiment include every disclosed tile family. Nor does it require that all tile families be active at all times. Rather, the platform is defined by the ability to host, electrically aggregate, and controller-coordinate at least two physically distinct harvesting domains on one substrate, one bus, and one controller.

With reference to FIG. 4, a shared substrate assembly 400 supports a plurality of modular tile structures implemented on the shared chi-lattice resonator substrate. In the illustrated embodiment, the shared substrate assembly 400 includes a vibration tile 402 having an FeGaB rib structure 404 and a PZT layer 406, a mid-IR rectenna tile 408 having a phi-spiral antenna grid 410 and a MIM diode 412, a thermoradiative tile 414 having a graphene/hBN RTD emitter 416, and a near-field TPV tile 418 having an HMM emitter 420, a GaSb receiver 422, and a sub-wavelength gap 424. FIG. 4 is intentionally organized to show representative tile families as modular embodiments implemented on the shared chi-lattice resonator substrate. The figure therefore reinforces that the preferred tile families are hosted on the disclosed unifying substrate framework rather than on an unspecified generic support structure. The figure also reinforces that the platform identity resides in the shared chi-lattice resonator substrate, the common chi-bus backplane, and the recognition-guided adaptive controller rather than in any single tile family considered in isolation.

The generic modular tile architecture of the platform may therefore be described as follows. A shared chi-lattice resonator substrate supports plural tile families. Each tile family defines one or more harvesting channels associated with a selected physical domain. Each channel is electrically coupled to the common chi-bus backplane, monitored and evaluated by the recognition-guided adaptive controller, and dispatched in accordance with the platform timing and quantization rules described herein. Because the tile families are implemented on the same shared chi-lattice resonator substrate and coupled to the same common chi-bus backplane, they can be treated as constituent platform elements rather than as externally aggregated devices.

Because the controller ranks active channels by J-cost and gates extraction to permitted windows within the eight-tick cadence, the plural tile families can also be managed under a common dispatch logic instead of under unrelated source-specific control loops.

A first preferred tile family is a vibration tile family configured to harvest mechanical vibration energy. In the illustrated embodiment, the vibration tile 402 includes the FeGaB rib structure 404 and the PZT layer 406 arranged on a resonant support geometry implemented on the shared chi-lattice resonator substrate. In some preferred implementations, the vibration tile family may further include a phi-spiral cantilever geometry or a related resonant beam or rib structure selected to support harvesting across a targeted vibration band. The FeGaB rib structure 404 may provide a magnetostrictive response, while the PZT layer 406 may provide a piezoelectric response, so that dual transduction pathways may contribute to harvested output. Other embodiments may employ one of these effects more strongly than the other, or may emphasize one transduction pathway depending on the intended use case, available vibration environment, and fabrication constraints. What remains important is that the vibration tile family is integrated into the shared chi-lattice resonator substrate and the common bus architecture and is not treated as a separately controlled auxiliary harvester.

In preferred embodiments, the vibration tile family may operate across a selected mechanical band, such as approximately 40 Hz to 260 Hz in one preferred implementation, although other bands may be used. A preferred frequency cascade may follow a golden-ratio progression across available modes, thereby aligning the vibration tile family with the broader modal logic of the disclosed platform. In some embodiments, the tile family may include multiple resonant structures tuned to different sub-bands within a target vibration environment. In other embodiments, different cantilever geometries, rib spacings, transduction layer placements, proof-mass configurations, or mode selections may be used. The present disclosure does not require one exact vibration microgeometry so long as the resulting tile family remains implemented on and aligned to the shared chi-lattice resonator substrate and remains electrically and controller-integrated into the platform.

Mechanical vibration amplitude, mechanical frequency content, structural oscillation state, or combinations thereof may serve as representative inputs to the vibration tile family. Harvested electrical power delivered to the common chi-bus backplane serves as a representative output. In some disclosed embodiments, extraction from the vibration tile family is E_coh-locked and coordinated through the platform controller so that harvested energy is dispatched in accordance with the same J-cost ranking, eight-tick gating, and E_coh quantization logic applied elsewhere on the platform. The vibration tile family is therefore not merely a source converter attached to the platform; it is one of the preferred modular domain implementations through which the platform realizes cross-domain harvesting.

A second preferred tile family is a mid-IR rectenna tile family configured to harvest thermal photon flux within a selected mid-infrared band. In the illustrated embodiment, the mid-IR rectenna tile 408 includes the phi-spiral antenna grid 410 and the MIM diode 412 arranged to receive incident thermal radiation and convert that radiation into electrical output. In preferred embodiments, the antenna grid may be directional, chi-grid based, or phi-spiral based, with a selected pitch relation tied to a target wavelength or wavelength band. Preferred implementations may target the atmospheric window in the 8 um to 14 um region, although other radiative bands may also be used in embodiments consistent with the disclosed platform architecture. The MIM diode 412 may be implemented as a tunneling conversion element configured to rectify the received radiative signal into electrical output suitable for routing onto the common chi-bus backplane.

In preferred embodiments, the rectenna pitch may scale with target wavelength according to a selected relation preserving compatibility with the chi-lattice resonator logic and desired operating band. The rectenna tile family may be dimensioned or tuned to favor the 8 um to 14 um atmospheric window and may provide responsivity greater than 6 A/W in a preferred implementation, with the antenna geometry and pitch selected to preserve compatibility with the shared chi-lattice resonator framework while targeting the atmospheric-window band. Those numerical values are exemplary and support specific embodiments; they should not be understood as universal limitations of all rectenna-family embodiments. Other embodiments may use alternative antenna densities, different diode stacks, different metallization choices, different dielectric arrangements, or different spectral emphasis so long as the rectenna tile family remains integrated into the shared chi-lattice resonator substrate, electrically coupled to the common chi-bus backplane, and coordinated by the recognition-guided adaptive controller.

Thermal photon flux in the target band serves as a representative input to the rectenna tile family.

Harvested electrical power delivered into the common bus serves as a representative output. In some embodiments, the rectenna harvesting channel may be prioritized when incident radiative conditions produce a recognition ratio associated with low J-cost. In other words, the rectenna channel need not operate in isolation or under a rectenna-specific control doctrine. Instead, it is one of the channels evaluated and ranked by the controller as part of the platform-wide dispatch architecture. This integration is important because prior hybrid systems often combine radiative and non-radiative harvesting structures without a shared resonator framework or without a principled dispatch rule. Here, the rectenna tile family is a preferred platform member operating under the same shared substrate, shared bus, and shared controller architecture as the other tile families.

A third preferred tile family is a thermoradiative tile family configured to harvest energy from a hot-above-cold radiative condition. In the illustrated embodiment, the thermoradiative tile 414 includes the graphene/hBN RTD emitter 416 arranged as a resonant tunnel diode emitter associated with a selected cavity condition. In one preferred implementation, the thermoradiative structure may be matched to a cavity resonance near 3.2 um. The thermoradiative tile family may therefore convert a radiative imbalance associated with a hot-above-cold operating condition into harvested electrical output. In some embodiments, the thermoradiative tile family may be modeled with reference to a Stefan-Boltzmann flux difference or related radiative-power relation, while in other embodiments alternative modeling approaches may be used. The important point is that the thermoradiative tile family remains one of the preferred baseline harvesting domains integrated into the disclosed platform.

Representative inputs to the thermoradiative tile family may include thermal gradient, cavity condition, hot-side temperature, cold-side temperature, radiative coupling condition, or combinations thereof. Harvested electrical power delivered to the common chi-bus backplane serves as a representative output. In preferred embodiments, the disclosure preserves the proposition that positive-power operation is obtained for hot-above-cold configurations consistent with the disclosed architecture. The thermoradiative channel may therefore be used as a source path within the same controller-managed channel set as vibration, rectenna, and near-field TPV harvesting channels. In some platform states, the thermoradiative channel may be relatively more favorable than other channels. In other states, it may be relatively less favorable.

In either case, dispatch is handled under the common recognition-guided adaptive controller rather than under an isolated thermoradiative-specific control regime.

The thermoradiative tile family may be varied in different embodiments through adjustment of cavity design, emitter structure, graphene or hBN layer arrangement, encapsulation approach, thermal interface design, and related parameters. Such variations do not alter the platform identity of the invention. Rather, they provide flexibility in implementing one preferred harvesting domain family on the shared chi-lattice resonator substrate while preserving electrical aggregation through the common chi-bus backplane and coordinated dispatch through the recognition-guided adaptive controller.

A fourth preferred tile family is a near-field TPV tile family configured for near-field thermophotovoltaic harvesting. In the illustrated embodiment, the near-field TPV tile 418 includes the HMM emitter 420, the GaSb receiver 422, and the sub-wavelength gap 424. In preferred embodiments, the HMM emitter 420 may be configured as a hyperbolic metamaterial emitter having phi-scaled layer relationships, and the near-field structure may further include sub-wavelength separation maintained by spacer structures, including about 100 nm SiO2 standoffs in one preferred implementation. The GaSb receiver 422 may be positioned across the sub-wavelength gap 424 to receive near-field radiative transfer from the emitter structure. In some implementations, the in-plane geometry of the near-field TPV tile family may follow the chi-lattice resonator framework so that the tile family remains integrated not only electrically and operationally, but also geometrically, with the shared substrate logic of the platform.

Representative inputs to the near-field TPV tile family may include emitter temperature, receiver temperature, nanogap or sub-wavelength gap condition, spectral coupling condition, or combinations thereof. Harvested electrical power delivered into the common chi-bus backplane serves as a representative output. In one preferred example, the near-field TPV tile family may provide a relatively high per-area output compared with other baseline tile families, although exact densities and outputs remain example-specific and should not be read as universal limitations. The near-field TPV channel, like the other tile-family channels, is evaluated by the controller through the common channel-state and J-cost logic and dispatched according to platform timing and quantization rules. Thus, even though the near-field TPV channel may be physically and operationally distinct from the vibration, rectenna, and thermoradiative channels, it is not architecturally separate from the platform. It is a preferred modular constituent of that platform.

The preferred baseline tile set therefore includes the vibration tile family, the mid-IR rectenna tile family, the thermoradiative tile family, and the near-field TPV tile family. These preferred tile families are exemplary implementations of the disclosed platform and do not redefine the invention away from the chi-lattice-resonator-based platform architecture itself. They are important and should be described thoroughly, but they remain subordinate to the platform-level invention. A two-domain minimum embodiment may still satisfy the cross-domain requirement, and supported subsets of the preferred baseline tile set may also be used in different embodiments.

Other tile families and harvesting domains may be supported where implemented consistently with the disclosed shared chi-lattice resonator substrate, the common chi-bus backplane, and the recognition-guided adaptive controller architecture described herein. However, non-baseline domain types should remain subordinate to the disclosed platform architecture. For example, a dual-band ledger tile may be included as an optional or continuation-oriented embodiment. A vacuum Casimir domain embodiment may be described as prophetic, future-facing, or continuation-oriented unless and until additional support elevates such embodiments beyond that status. Likewise, if the specification refers generally to other physically distinct harvesting domains, such statements should be understood as cabined by the requirement that those domains be implemented consistently with the disclosed shared substrate, shared bus, and shared controller framework. The present disclosure does not use speculative domain breadth to redefine the invention away from its actual platform architecture.

The common chi-bus backplane provides the electrical aggregation structure through which harvested energy and associated control or sensing information are routed on the platform. With reference to FIG. 5, a chi-bus backplane 500 includes a plus DC rail 502, a minus return rail 504, a CAN-FD high line 506, and a CAN-FD low or shield line 508. One or more impedance-matching networks 510 couple respective tile families to the chi-bus backplane 500. One or more shunt monitors 512 may sense per-tile current or related operating parameters, and one or more bias-control interfaces 514 may be used for controller-directed bias adjustment. Harvested energy may be routed to a storage element 516, an external load 518, and an output node 520.

FIG. 5 is intended to show that the platform is not merely a mechanical co-location of different harvester types, but an electrically integrated architecture in which plural tile families are aggregated through a common chi-bus backplane.

In preferred embodiments, the chi-bus backplane is a four-wire bus arrangement that carries both electrical power and control or data signaling. Preferred implementations may employ nominal rails such as plus or minus 28 V DC and a characteristic impedance such as 50 ohms, and in one preferred implementation the common chi-bus backplane operates at an efficiency of about 0.91 with a bus current limit of about 75 mA, but those values are preferred implementation details rather than universal limitations. In one implementation, the selected bus impedance refers to the nominal characteristic impedance adopted for the chi-bus backplane and associated matching networks. What is central is that the common chi-bus backplane provides one common bus architecture through which plural harvesting channels are electrically aggregated and controller-coordinated. The bus is passive and lossy, not generative, and routes, conditions, and aggregates harvested power from the tile families while accommodating associated sensing and control traffic. This proposition is important because it distinguishes the disclosed bus architecture from any implication that net platform gains arise from the bus itself rather than from coordinated harvesting across plural channels.

The present disclosure preserves theorem-backed bus properties as part of the platform story rather than as isolated mathematical curiosities. In disclosed embodiments, net output does not exceed gross output. In disclosed embodiments, a panel having positive-power channels and positive bus efficiency yields positive net output. These propositions reinforce the exact architectural role of the common chi-bus backplane. The bus is passive and lossy, not generative.

It may reduce output relative to gross harvested input due to real routing and coupling losses, but it does not negate the platform's ability to deliver positive aggregate output when plural positive-power channels are present and bus efficiency is positive. These propositions are therefore part of the platform's structural and operational credibility and should not be reduced to after-the-fact validation commentary.

In preferred embodiments, impedance matching between tile modules and the common chi-bus backplane follows phi-ladder impedance steps according to Z_n=Z0*phi\hat{ }n. Such matching structures may be implemented in the impedance-matching networks 510 and may be used to transform native tile impedances toward a selected bus impedance. The phi-ladder impedance approach is a strong fallback position because it ties electrical matching to the broader phi-structured architecture of the platform rather than treating matching as a generic convenience circuit. In some embodiments, different matching stages may be associated with different tile families or different operating states, but the use of phi-ladder impedance steps preserves a common architectural logic across the backplane and channel-coupling structures.

In preferred embodiments, tile outputs may be series-stacked on the DC rail. The controller may monitor per-tile current through the shunt monitors 512, including one or more shunt resistors, current-sense amplifiers, analog-to-digital converter inputs, or combinations thereof, while adjusting tile bias through the bias-control interfaces 514, including one or more digitally controlled bias drivers, gate-control circuits, switched-capacitor stages, switched-inductor stages, or combinations thereof. A bus current limit may also be enforced under a selected qualification profile. These details support concrete implementation, but the broader architectural point remains that the common chi-bus backplane provides one common bus architecture through which plural distinct-domain harvesting channels are electrically coordinated and aggregated.

That architecture allows harvested output from mechanically distinct, radiatively distinct, and thermally distinct tile families to be combined without collapsing the invention into a mere wiring diagram. Instead, the bus functions as one of the co-equal pillars of the platform.

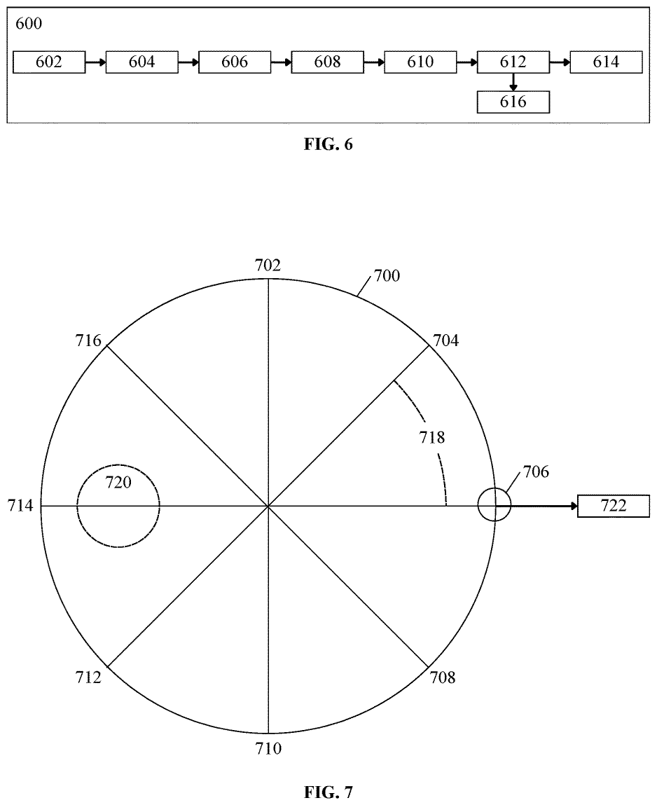

The recognition-guided adaptive controller provides the cross-domain control strategy by which active channels are evaluated, ranked, phase-checked, and dispatched. With reference to FIG. 6, a controller 600 may perform channel-state intake 602, recognition-ratio evaluation 604, J-cost ranking 606, phase evaluation 608, dispatch gating 610, quantized transfer control 612, common-bus routing 614, and optional telemetry output 616. In one non-limiting implementation, channel-state intake 602 samples each active channel at a cadence Ts in a range of 1 ms to 50 ms and obtains a bus-side voltage Vch and a bus-side current Ich for the channel. Recognition-ratio evaluation 604 may compute a recognition ratio x=(Vch*Ich)/Pref, where Pref is a stored reference power associated with the channel or channel family. Dispatch gating 610 may define a permitted dispatch window width W of 1 to 3 ticks within each eight-tick cycle, and quantized transfer control 612 may authorize extraction for a selected channel when J(x)<=Jmax and abs(DeltaC)<=Ctol, where C_cycle is computed as a time-integral or discrete sum of bus-side current over the current eight-tick cycle multiplied by tick duration, DeltaC=C_cycle−C_ref, C_ref is a stored cycle-charge reference computed from one or more preceding eight-tick intervals, Jmax is in a range of 0.01 to 0.25, and Ctol is in a range of 0.1 percent to 5 percent of C_ref. If either condition is not satisfied, extraction for the selected channel may be inhibited without switching the power path until a later admissible phase, or dispatch may be reassigned to a next-ranked channel. In one implementation, quantized transfer control 612 enforces transfer in integer packet multiples of E_coh using an accumulator, counter, switched-capacitor stage, switched-inductor stage, pulse-width-controlled transfer stage, or combinations thereof. These depicted functions are exemplary controller functionality rather than a mandatory software-module partition. The invention does not require that each function be instantiated as a separately bounded software module or hardware block. Instead, FIG. 6 presents the controller in functional terms to illustrate how channel-state information is received, evaluated, ranked, phase-checked, and used to control extraction and transfer on the platform.

In the disclosed platform, the recognition-guided adaptive controller evaluates channel state using a recognition ratio, ranks active channels by J-cost, gates extraction to permitted windows within the eight-tick cadence, permits dispatch of a phase-locked bundle when a common admissible phase is available, switches a power path for a selected channel when dispatch conditions are satisfied, and quantizes transfer to integer multiples of E_coh, where E_coh=phi\hat{ }−5. The recognition-guided adaptive controller refers to the disclosed controller architecture in which recognition-ratio evaluation, J-cost ranking, eight-tick dispatch gating, phase-locked bundle dispatch, and E_coh-quantized transfer are coordinated as a common cross-domain control strategy. Preferred controller hardware may include one or more microcontrollers, processor cores, programmable logic structures, distributed controller nodes, bus interfaces, analog-to-digital converter circuitry, current-sense circuitry, voltage-sense circuitry, non-transitory memory storing dispatch instructions, switching drivers, gate-control circuitry, or related control circuitry, including a distributed controller matrix in one preferred implementation, but exact hardware selection is embodiment-specific and not universally core.

What remains core is the controller rule set and its integration with the shared substrate and common bus.

The controller workflow may be described functionally as follows. The controller identifies active channels on the platform and obtains channel-state information, which may include channel identity, harvesting domain, recognition ratio, channel phase, power-density information, bus state, or combinations thereof. The controller then evaluates J-cost according to J(x)=½(x+1/x)−1. Active channels are ranked by ascending J-cost so that the channel closest to ratio unity is preferred for dispatch. The controller next determines whether a permitted dispatch window is present within the eight-tick cadence and, where applicable, whether plural channels form a phase-locked bundle sharing a common admissible phase, and may further determine whether J(x)<=Jmax and abs(DeltaC)<=Ctol for a selected channel before extraction is authorized. If dispatch conditions are met, including satisfaction of J(x)<=Jmax and abs(DeltaC)<=Ctol for a selected channel, extraction is gated in accordance with the eight-tick cadence, a power path for the selected channel is switched for dispatch, transfer is quantized to integer multiples of E_coh, and harvested energy is routed to the common chi-bus backplane for delivery to storage structures, load structures, or both. Logging, maintenance, diagnostics, headroom screening, bias optimization, and related implementation refinements may also be used, but such refinements are optional implementation detail rather than part of the irreducible disclosed controller rule set.

This controller architecture differs from generalized maximum power point tracking approaches.

Conventional MPPT techniques are ordinarily designed around smooth, substantially monotonic power-voltage behavior and are typically applied source by source. By contrast, the present controller architecture is recognition-guided, cross-domain, and phase-aware. It ranks active channels by J-cost. It gates extraction to permitted windows within the eight-tick cadence. It permits phase-locked bundle dispatch when plural channels share a common admissible phase. It quantizes all energy transfers on the platform to integer multiples of E_coh. These distinctions matter because the disclosed platform is not merely managing several analog sources with conventional optimization loops. It is coordinating plural distinct-domain channels under an exact platform-wide dispatch logic. In particular, for modal or otherwise non-monotonic transducers, including rectenna structures, magnetostrictive structures, and near-field cavity-based structures, the disclosed controller improves on conventional MPPT by selecting dispatch based on recognition-ratio state, J-cost ranking, admissible phase, and ledger-neutral timing rather than assuming a single smooth power-voltage optimum for each source.

With reference now to FIG. 7, an eight-tick cycle 700 includes tick 0 at 702, tick 1 at 704, tick 2 at 706, tick 3 at 708, tick 4 at 710, tick 5 at 712, tick 6 at 714, and tick 7 at 716. One or more permitted dispatch windows 718 may be defined within that cycle. A phase-locked bundle 720 may be dispatched when plural channels share a common admissible phase. The resulting complete cycle yields a ledger-neutral cycle result 722. The phase-cancellation identity sum_{k=0}\hat{ }{7} exp(2pii*k/8)=0 forces an eight-phase ledger cycle. In the disclosed controller architecture, extraction is gated to permitted windows within that eight-tick cadence, and every complete cycle leaves the ledger exactly neutral. Phase-locked bundle dispatch occurs when plural channels share a common admissible phase, and at least one admissible dispatch phase exists. This timing discipline is not merely generic synchronization. It is part of the exact cross-domain control strategy by which the platform preserves ledger-neutral operation across plural harvesting channels.

The eight-tick cadence should be understood as a platform timing rule, not as a decorative theoretical label. In one non-limiting implementation, ledger neutrality over an eight-tick cycle is evaluated using accumulated cycle charge computed as a time-integral or discrete sum of bus-side current over the eight ticks multiplied by tick duration, optionally signed by rail direction, so that DeltaC represents deviation of that accumulated cycle charge from a stored reference for the cycle. In one implementation, each channel maintains a phase tag in the eight-tick cycle derived from a controller timing reference, a bus timestamp, or a phase-locked loop synchronized to the eight-tick cadence. A channel is phase-locked when its phase tag remains within plus or minus 1 tick of a bundle phase tag over a preceding N-cycle window, where N is 1 to 10. When the disclosure states that the phase-cancellation identity forces an eight-phase ledger cycle, that statement should be read firmly. When the disclosure states that phase-locked bundle dispatch occurs when plural channels share a common admissible phase, that statement should likewise be read firmly. When the disclosure states that at least one admissible dispatch phase exists, that statement should also be preserved in its exact form. These exact propositions supply support not only for the controller narrative, but also for narrower fallback claims directed to dispatch phase existence, phase-locked bundle dispatchability, and eight-tick-gated extraction, and in disclosed embodiments machine-verified support includes exists_dispatch_phase and phase_locked_bundle_dispatchable style propositions at the platform level. They also help distinguish the present platform from control schemes that merely sample or synchronize channels without a disclosed ledger-neutral phase discipline.

The platform further preserves exact transfer quantization. In the disclosed architecture, E_coh=phi\hat{ }−5, and all energy transfers on the platform are quantized to integer multiples of E_coh.

Quantization to integer multiples of E_coh, together with extraction gated to permitted windows within the eight-tick cadence, preserves ledger-neutral operation across the complete cycle.

Where the disclosure identifies coherence exponent=5 as forced, certified, or family-verified, that coherence exponent=5 is preserved as part of the disclosed platform logic rather than replaced with weaker paraphrase. The present disclosure therefore consistently preserves the exact proposition that all energy transfers on the platform are quantized to integer multiples of E_coh. This statement should not be diluted into generic references to coherence-based transfer, quantized-like transfer, or optimized packet transfer. The disclosed rule is exact: all energy transfers on the platform are quantized to integer multiples of E_coh.

The recognition-guided adaptive controller also preserves calibration transfer and recognition-geometry composition across platform conditions. Policies expressed in dimensionless recognition coordinates transfer across platform calibrations without changing the argmin set.

This means that a controller policy developed under one calibration condition can remain valid after recalibration so long as the policy is expressed in the relevant dimensionless recognition coordinates. This property matters because field recalibration, maintenance recalibration, replacement-part recalibration, and deployment-specific recalibration need not force controller logic to be redesigned from scratch. The platform therefore preserves controller portability at a deeper level than mere parameter copying. It preserves the policy decision structure itself when expressed in the relevant dimensionless recognition coordinates.

In addition, the composite recognizer constructed from plural source modalities refines the component recognition structures rather than degrading them. In practical terms, the platform-level recognition map is at least as informative as the component source maps used to construct it. This proposition provides narrower fallback support for claims directed to calibration-transfer invariance and composite-domain control and further reinforces that the recognition-guided adaptive controller is not generic supervisory software. It is a controller architecture grounded in exact cross-domain ranking, timing, transfer, and policy-transfer logic.

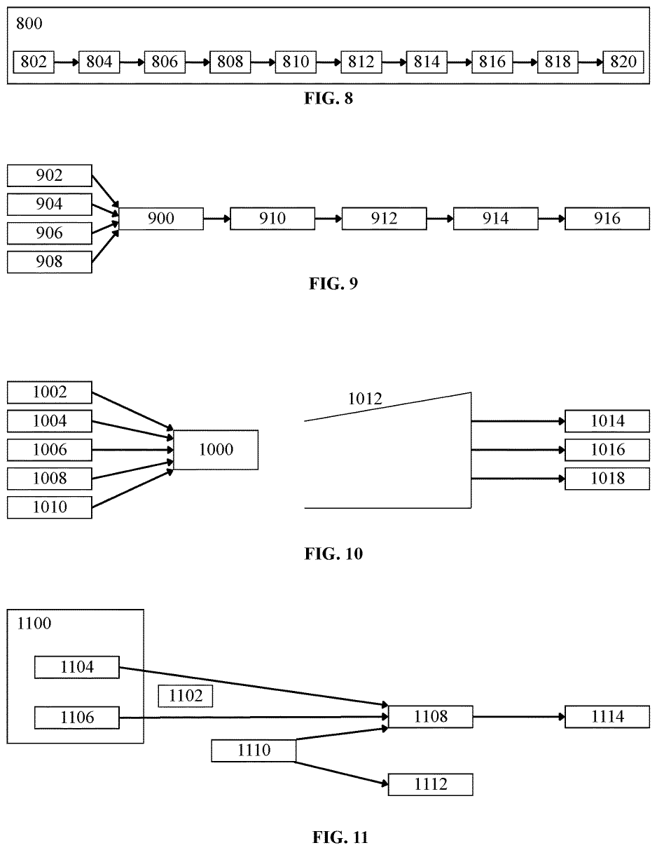

The disclosed platform may be made and assembled using a fabrication approach that preserves the common-substrate, common-fiducial architecture described above. With reference to FIG. 8, a fabrication flow 800 may begin with formation or provision of a SiO2 substrate 802 and deposition or formation of a Si3N4 membrane 804. A chi-apex fiducial pattern 806 is then formed so that subsequent tile-family formation steps can be aligned to common chi-apex fiducials on the same chi-lattice resonator substrate. One or more vibration tile deposition steps 808, rectenna deposition steps 810, thermoradiative deposition steps 812, and TPV deposition steps 814 may then be carried out in sequence on the same substrate. A chi-bus formation step 816 electrically couples the resulting tile families into the common bus architecture, after which encapsulation or packaging 818 may be performed to produce a completed multi-domain panel 820. This fabrication sequence is illustrative rather than limiting, but it preserves an important structural and manufacturing distinction of the invention, namely that plural distinct-domain tile families are aligned to common fiducials on the same chi-lattice resonator substrate rather than separately fabricated and later combined in an ad hoc hybrid assembly.

In preferred embodiments, formation of the substrate stack begins with a support substrate capable of carrying the membrane and resonator structures while maintaining sufficient dimensional stability for common-fiducial alignment. A SiO2 support substrate is preferred in one implementation, and a low-stress Si3N4 membrane is preferred in one implementation, but other support-stack combinations may be used provided that they preserve the disclosed chi-lattice resonator framework and permit the required cross-domain alignment. After the membrane is formed, the chi-lattice resonator geometry and common chi-apex fiducials may be patterned so that subsequent tile-family formation steps inherit a common alignment reference.

This is materially different from separately fabricating domain-specific devices and attempting to register them later in packaging. In the disclosed approach, the common-fiducial alignment of plural tile families on the same substrate is built into the fabrication flow itself.

Sequential deposition or formation of plural tile families may then proceed in any order consistent with process compatibility, contamination control, thermal budget, and alignment preservation. For example, one fabrication sequence may begin with formation of vibration-harvesting structures, proceed to rectenna-related metallization and diode formation, proceed to thermoradiative emitter formation, and proceed to near-field TPV structure formation. Another sequence may alter that order to accommodate process integration constraints. The invention does not depend on one exact sequence so long as plural distinct-domain tile families are implemented on and aligned to the same shared chi-lattice resonator substrate. This preserves support for fabrication claims directed not merely to a generic manufacturing method, but to a method in which plural distinct-domain tile families are aligned to common fiducials on the same substrate, sequentially deposited or formed in process-compatible order, electrically coupled into a common chi-bus architecture, and integrated so that inter-tile registration error associated with separately fabricated hybrid assemblies is reduced or eliminated.

Following tile-family formation, the common chi-bus backplane may be formed, connected, or otherwise integrated so that the tile families are electrically coupled into the common aggregation architecture. Encapsulation, packaging, sealing, passivation, protective layering, and interface formation may then be performed as appropriate for the intended use case. In some embodiments, packaging may be optimized for industrial heat exposure. In other embodiments, packaging may be optimized for roadway embedding, building integration, or other downstream contexts. The completed article may therefore be embodied as a manufactured panel, module, tile array, insert, or surface-integrated energy-harvesting article configured for later installation or deployment. These packaging choices are implementation detail and do not redefine the platform-level invention. What remains central is that the completed article preserves the shared chi-lattice resonator substrate, the common chi-bus backplane, and the recognition-guided adaptive controller architecture described herein.

Platform operation may be understood as an exemplary sequence rather than as a mandatory fixed protocol. In one exemplary operational sequence, the platform identifies active channels, obtains channel-state information including recognition ratio and phase state, evaluates J-cost for active channels, ranks the active channels by ascending J-cost, determines whether a permitted dispatch window is present and whether a phase-locked bundle condition exists, determines whether J(x)<=Jmax and abs(DeltaC)<=Ctol for a selected channel, switches a power path for the selected channel when both conditions are satisfied, gates extraction in accordance with the eight-tick cadence, quantizes transfer to integer multiples of E_coh, routes harvested energy to the common chi-bus backplane and associated storage or load circuitry, and optionally generates telemetry, maintenance, or diagnostic output. Dynamic reconfiguration among tile families as environmental conditions change may also be performed. For example, one tile family may dominate during one environmental condition while another tile family is dispatched preferentially during a different condition, with the controller maintaining platform-level coordination through the common chi-bus backplane and the recognition-guided adaptive control logic.

This exemplary operational sequence is important because it demonstrates that the present invention is not limited to static coexistence of different tile families. The platform is adaptive in the sense that channel conditions may change over time and dispatch may be reallocated accordingly. Yet that adaptivity is not unconstrained. It occurs within the disclosed controller rule set, including recognition-ratio evaluation, J-cost ranking, eight-tick gating, phase-locked bundle dispatch where applicable, and E_coh-quantized transfer. Thus, the platform may respond dynamically without collapsing into an unspecified adaptive-control system. Its dynamic behavior remains anchored to the disclosed cross-domain control strategy. In installed-system embodiments, the platform may be electrically coupled to one or more storage structures, power-conditioning structures, fixed or mobile load structures, supervisory controllers, site power buses, or combinations thereof without departing from the same shared-substrate, shared-backplane, and recognition-guided controller architecture.

A preferred embodiment may be configured as a baseline multi-domain panel. With reference to FIG. 9, a baseline panel 900 receives a vibration input stream 902, a rectenna input stream 904, a thermoradiative input stream 906, and a TPV input stream 908. The harvested outputs are aggregated at a gross output node 910, routed through a bus-efficiency stage 912, and delivered as net output at a net output node 914 to a storage or load interface 916. In one preferred example, a 300 mm×300 mm panel includes vibration, mid-IR rectenna, thermoradiative, and near-field TPV tile families and produces a gross output equal to the sum of respective channel outputs, with net output reflecting bus efficiency, and in one illustrative computation the channel contributions are about 18 W, 12 W, 35 W, and 67 W, respectively, for a gross output of about 132 W and a net output of about 120.12 W at about 0.91 bus efficiency. This example is a preferred full-platform embodiment and numerical example rather than a universal claim limitation. It is useful because it shows the platform in its preferred four-domain form while still presenting the outputs as example-specific rather than definitionally mandatory.

A breadth-preserving minimum embodiment may be provided with fewer than four tile families.

With reference to FIG. 11, a minimum platform 1100 includes a shared chi-lattice substrate 1102, a vibration tile family 1104, a mid-IR rectenna tile family 1106, a chi-bus backplane 1108, a controller 1110, a ranked dispatch path 1112, and an output node 1114. This embodiment demonstrates that the invention does not require all preferred tile families to be present simultaneously in order to remain a cross-domain platform. So long as at least two physically distinct domains are implemented on the shared chi-lattice resonator substrate, electrically coupled through the common chi-bus backplane, and coordinated by the recognition-guided adaptive controller, the platform character of the invention is preserved. This minimum embodiment is important because it preserves breadth below the all-four-family preferred embodiment.

In one illustrative two-domain example, vibration harvesting and mid-IR rectenna harvesting are combined on the same platform, with about 18 W from the vibration channel and about 12 W from the rectenna channel in one representative computation, yielding about 30 W gross and about 27.3 W net at about 0.91 bus efficiency. This minimum configuration remains cross-domain because the harvesting domains are physically distinct, and it remains within the invention because the channels are implemented on the shared chi-lattice resonator substrate, coupled through the common chi-bus backplane, and controller-coordinated under the same recognition-guided adaptive logic. This example is particularly important for prosecution because it shows that the invention is not limited to the preferred all-four-family panel.

Worked examples may therefore be used to illustrate operation of the disclosed platform without redefining the invention as a set of fixed benchmark values. A baseline four-domain panel may be used as a preferred full-platform example. A two-domain minimum platform may be used as a breadth-preserving fallback example. Other examples may model different mixtures of tile families and operating conditions without altering the platform-level identity of the invention.

The purpose of these examples is to provide concrete make-and-use style support, demonstrate platform operation across more than one channel mix, and distinguish between preferred embodiments and the broader architecture that supports them, including manufactured-article, installed-system, and deployment-oriented embodiments consistent with the same platform pillars.

Reliability and validation may also be described with reference to FIG. 10. A qualification profile 1000 may include a humidity or temperature test 1002, a bus-current test 1004, a vibration test 1006, a thermal-shock test 1008, and a salt-fog test 1010. Measured degradation behavior may be represented by a degradation curve 1012, and a failure-mode summary 1014 may describe observed engineering behavior. Formal support anchors may include a Lean theorem set 1016 and an umbrella viability result 1018. FIG. 10 is intended to place measured engineering qualification material and formal support anchors in one figure while still keeping those categories analytically separate.

In one engineering qualification profile, testing may be performed under conditions including elevated temperature and humidity exposure, sustained bus current, vibration exposure, thermal shock, and salt-fog exposure. Representative engineering observations may include net power degradation after a selected run duration, channel-specific degradation breakdowns, absence of bus faults during the disclosed qualification run, absence of CAN-FD errors during the disclosed qualification run, observed failure modes associated with particular tile families or interconnect structures, and Arrhenius-based lifetime estimation using an activation energy of about 0.79 eV in one engineering estimate. Arrhenius lifetime projection may also be provided as an engineering estimate or extrapolation rather than as direct lifetime demonstration. These engineering observations are useful because they show that the platform can be described not only theoretically, but also in terms of environmental qualification, degradation behavior, and failure analysis, and because they permit correlation of qualification results with platform-level example outputs including about 132 W gross output, about 120.12 W net output, and about 0.91 bus efficiency in the baseline panel example.

At the same time, the disclosure keeps measured engineering material, machine-verified material, worked numerical examples, and prophetic material in separate descriptive lanes.

Measured engineering material may include qualification conditions, degradation observations, no-bus-fault observations, no CAN-FD-error observations, and failure-mode observations.

Machine-verified material may include odd-index mode properties, positive mode pitch, positive total power for nonempty channel lists, positive scheduled output, dispatchability of a phase-locked bundle, existence of an admissible dispatch phase, calibration-transfer invariance, and theorem-backed gross or net output bounds where applicable. Worked numerical examples include the baseline panel and minimum-platform output calculations. Prophetic or future-facing material remains separate and should not be blended into the same support category. This disciplined separation of support types is important because it prevents the specification from overstating what is directly measured, what is machine-verified, what is numerically worked, and what is future-facing.

The disclosure may also include a formal verification and credibility section. Platform-level theorems, family certificates, upstream Recognition Science kernel references, and an umbrella platform viability theorem may be included as support and credibility anchors for exact constants, exact ordering, exact invariants, and exact platform assertions, including theorem-backed propositions corresponding to odd-index mode verification, positive mode pitch, positive aggregate output for nonempty channel sets, positive scheduled output, dispatchability of a phase-locked bundle, existence of an admissible dispatch phase, controller-policy transfer across recalibration without changing the argmin set, net output less than or equal to gross output, and umbrella platform viability. In non-limiting examples, such theorem-backed propositions may be associated with theorem or certificate identifiers including chiMode_odd, exists_dispatch_phase, and phase_locked_bundle_dispatchable. Such formal support is not the sole enablement mechanism of the disclosure, but it provides substantial reinforcement for the disclosed propositions that the platform yields positive aggregate output, that dispatch phase exists, that phase-locked bundle dispatch occurs when plural channels share a common admissible phase, that common-fiducial alignment is maintained across plural tile families, and that the shared chi-lattice resonator substrate supports cross-scale operation across optical, thermal, and elastic regimes. Broad independent claims need not require formal verification as an express limitation, but the present disclosure preserves support for narrower claims, dependent claims, or later continuation strategies directed to verification-based subject matter, including verification of odd-index mode behavior, positive mode pitch, positive aggregate output for nonempty channel sets, positive scheduled output, existence of an admissible dispatch phase, dispatchability of a phase-locked bundle, controller-policy transfer across recalibration without changing an argmin set, and net output less than or equal to gross output, and further preserves support for fabrication-method, manufactured-article, installed-system, and downstream deployment claim positions consistent with the same shared-substrate, shared-backplane, and recognition-guided controller architecture.

In disclosed embodiments, machine-verified support may include verification that the odd-index mode family satisfies the proposition that m_n=2n+1 are always odd, verification that mode pitch remains positive across the disclosed resonator family, verification that positive aggregate power is obtained for nonempty channel sets, verification that scheduled output remains positive under the disclosed controller conditions, verification that a phase-locked bundle is dispatchable when plural channels share a common admissible phase, verification that at least one admissible dispatch phase exists, and verification that policies expressed in dimensionless recognition coordinates transfer across platform calibrations without changing the argmin set. These theorem-backed propositions serve as formal support for the exact platform architecture described herein. They should be understood as support and credibility anchors for the architecture, not as substitutes for the physical disclosure of structure, operation, fabrication, and use.

Family certificates may also be associated with particular preferred tile families. By way of example, family-level certificates may support forced, certified, or theorem-backed propositions associated with vibration harvesting, rectenna harvesting, thermoradiative harvesting, or near-field TPV harvesting. Where the disclosure identifies coherence exponent=5 as forced, certified, or family-verified, that exact proposition is preserved in the present specification.

Where the disclosure identifies eight-tick cancellation behavior as certified or family-verified, that exact proposition is likewise preserved. In this way, the formal support layer of the specification is used to reinforce exact constants, exact relationships, exact ordering, and exact platform assertions without allowing the broader Recognition Science framework to swallow the concrete device-and-system invention disclosed here.

The present disclosure preserves the proposition that the invention claims the platform as a whole. The shared chi-lattice resonator substrate, the common chi-bus backplane, and the recognition-guided adaptive controller collectively define the platform architecture, and the preferred tile families, examples, use cases, and validation sections remain subordinate to that platform identity.

It will therefore be understood that the foregoing figures, embodiments, fabrication sequences, operational sequences, numerical examples, reliability discussions, and formal-support discussions are illustrative and explanatory rather than limiting. Specific tile materials, exact bus voltages, exact bus impedances, exact bus efficiency values, exact controller hardware, exact telemetry rates, exact panel dimensions, exact tile counts, exact mounting details, exact encapsulation choices, exact packaging structures, exact deployment-specific load interfaces, and exact downstream use configurations may vary without departing from the invention. Likewise, industrial, roadway, building, military, agricultural, maritime, disaster-response, and space-related uses remain subordinate downstream applications rather than the identity of the invention. The preferred four-family panel likewise remains a preferred embodiment rather than a universal requirement.

Other physically distinct harvesting domains may be supported where such domains are implemented consistently with the disclosed chi-lattice resonator substrate, the common chi-bus backplane, and the recognition-guided adaptive controller architecture described herein.

However, optional, future-facing, prophetic, or continuation-oriented embodiments should remain subordinate to the supported core platform architecture. For example, vacuum Casimir embodiments, dual-band ledger embodiments treated as central platform members, and broad scale or commercialization projections should not be read as redefining the invention away from its disclosed platform pillars. The core invention remains a shared-substrate, shared-backplane, recognition-guided cross-domain harvesting platform.

Accordingly, the present disclosure provides a robust platform architecture for combining multiple heterogeneous energy-harvesting modalities on one shared chi-lattice resonator substrate, using one common chi-bus backplane and one recognition-guided adaptive controller to coordinate extraction, aggregation, dispatch, and transfer. The invention is not limited to the exact embodiments illustrated and described, and modifications, substitutions, re-orderings, and variations consistent with the claims may be made without departing from the scope of the invention.

What is claimed is:

1. A cross-domain energy-harvesting platform comprising: a shared chi-lattice resonator substrate; at least two tile families implemented on and aligned to the shared chi-lattice resonator substrate, the at least two tile families being configured to harvest energy from physically distinct domains; a common electrical backplane electrically coupled to the at least two tile families; and a recognition-guided adaptive controller configured to coordinate extraction and aggregation of harvested energy from the at least two tile families through the common electrical backplane.

2. The platform of claim 1, wherein the shared chi-lattice resonator substrate comprises a chi-lattice resonator having counter-diagonal geometry and an odd-index mode family defined by m_n=2n+1.

3. The platform of claim 2, wherein m_n=2n+1 are always odd, and odd symmetry ensures that transverse strain nodes coincide with longitudinal optical antinodes.

4. The platform of claim 2, wherein the chi-lattice resonator supports cross-scale operation across optical, thermal, and elastic regimes by variation of base pitch P0 while preserving the odd-index mode family.

5. The platform of claim 1, wherein the shared chi-lattice resonator substrate includes common chi-apex fiducials used to align plural tile families on the same substrate.

6. The platform of claim 5, wherein the common-substrate, common-fiducial approach reduces or eliminates inter-tile registration error relative to separately fabricated hybrid assemblies.

7. The platform of claim 1, wherein the recognition-guided adaptive controller is configured to evaluate channel state using a recognition ratio x=(Vch*Ich)/Pref computed from a bus-side voltage value Vch, a bus-side current value Ich, and a stored reference power Pref, and to rank active channels by J-cost.

8. The platform of claim 7, wherein J-cost is defined as J(x)=½(x+1/x)−1.

9. The platform of claim 7, wherein the recognition-guided adaptive controller is configured to rank active channels by ascending J-cost so that a channel closest to ratio unity is preferred for dispatch.

10. The platform of claim 1, wherein the recognition-guided adaptive controller is configured to gate extraction to permitted windows having a width of 1 to 3 ticks within an eight-tick cadence.

11. The platform of claim 10, wherein the phase-cancellation identity forces an eight-phase ledger cycle for the platform such that every complete cycle leaves a ledger state of the platform exactly neutral.

12. The platform of claim 10, wherein phase-locked bundle dispatch occurs when plural channels share a common admissible phase determined from respective channel phase tags, each channel phase tag being derived from a controller timing reference, a bus timestamp, or a phase-locked loop synchronized to the eight-tick cadence.

13. The platform of claim 10, wherein at least one admissible dispatch phase exists.

14. The platform of claim 1, wherein all energy transfers on the platform are quantized to integer multiples of a coherence quantum E_coh.

15. The platform of claim 14, wherein E_coh=phi\hat{ }−5.

16. The platform of claim 1, wherein the common electrical backplane comprises a chi-bus backplane having a plus DC rail, a minus return rail, a CAN-FD high line, and a CAN-FD low or shield line, and wherein the chi-bus backplane is passive and lossy, not generative.

17. The platform of claim 16, wherein the chi-bus backplane includes one or more impedance-matching networks configured to transform native tile impedances toward a selected bus impedance of the chi-bus backplane according to Z_n=Z0*phi\hat{ }n.

18. The platform of claim 1, wherein the platform is embodied as a manufactured panel, module, tile array, insert, or surface-integrated energy-harvesting article configured for installation and electrically coupled to one or more storage structures, power-conditioning structures, fixed or mobile load structures, supervisory controllers, site power buses, or combinations thereof.

19. A method of operating a cross-domain energy-harvesting platform, the method comprising:
obtaining channel-state information for at least two active harvesting channels associated with physically distinct domains on a shared chi-lattice resonator substrate, the channel-state information including a bus-side voltage value and a bus-side current value for each active harvesting channel; evaluating, for each active harvesting channel, a recognition ratio x=(Vch*Ich)/Pref using the bus-side voltage value, the bus-side current value, and a stored reference power Pref; ranking the at least two active harvesting channels by J-cost; determining whether a permitted dispatch window having a width of 1 to 3 ticks is present within an eight-tick cadence; determining whether J(x)<=Jmax and abs(DeltaC)<=Ctol for a selected active harvesting channel, where DeltaC represents a difference between accumulated cycle charge for a current eight-tick cycle and a stored cycle-charge reference; in response to both conditions being satisfied, switching a power path for the selected active harvesting channel and gating extraction from at least one of the at least two active harvesting channels in accordance with the permitted dispatch window; quantizing energy transfer to integer multiples of a coherence quantum E_coh, wherein E_coh=phi\hat{ }−5; and routing harvested energy through the common electrical backplane for aggregation.

20. A non-transitory computer-readable medium storing instructions that, when executed by one or more processors of a recognition-guided adaptive controller, cause the one or more processors to: obtain channel-state information for a plurality of harvesting channels associated with physically distinct domains of a cross-domain energy-harvesting platform, the channel-state information including a bus-side voltage value and a bus-side current value for each active harvesting channel; evaluate, for each active harvesting channel, a recognition ratio x=(Vch*Ich)/Pref using the bus-side voltage value, the bus-side current value, and a stored reference power Pref; rank active ones of the plurality of harvesting channels by J-cost;
determine whether a permitted dispatch window having a width of 1 to 3 ticks is present within an eight-tick cadence; determine whether J(x)<=Jmax and abs(DeltaC)<=Ctol for a selected active harvesting channel, where DeltaC represents a difference between accumulated cycle charge for a current eight-tick cycle and a stored cycle-charge reference; in response to both conditions being satisfied, switch a power path for the selected active harvesting channel, gate extraction for the selected active harvesting channel within the permitted dispatch window, dispatch a phase-locked bundle when plural channels share a common admissible phase, route harvested energy through the common electrical backplane for aggregation, and quantize energy transfer through the common electrical backplane to integer multiples of a coherence quantum E_coh, wherein E_coh=phi\hat{ }−5.
